(19) United States
(12) Patent Application Publication
(10) Pub. No.: US 2008/0218226 A1
(43) Pub. Date: Sep. 11, 2008

(54) CIRCUITS AND APPARATUS TO IMPLEMENT DIGITAL PHASE LOCKED LOOPS

(75) Inventor: Krishnaswamy Nagaraj, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/733,043

(22) Filed: Apr. 9, 2007

Related U.S. Application Data
(60) Provisional application No. 60/905,288, filed on Mar. 6, 2007.

(51) Int. Cl. H03L 7/00

(52) U.S. Cl. 327/147

(57) ABSTRACT

Circuits and apparatus to implement digital phase locked loops are disclosed. A disclosed example digital phase locked loop circuit comprises a phase detector to detect a phase difference between a reference signal and a feedback signal, a time digitizer to convert the phase difference to a digital value, and an adder to add an offset to the digital value, the offset selected to reduce a digital phase locked loop dead zone

### RELATED APPLICATIONS

This patent claims priority from U.S. Provisional Application Ser. No. 60/905,288, entitled “Elimination of Dead Zone in a DPLL,” filed on Mar. 6, 2007, and which is hereby incorporated by reference in its entirety.

### FIELD OF THE DISCLOSURE

This disclosure relates generally to digital phase locked loops and, more particularly, to circuits and apparatus to implement digital phase locked loops.

### BACKGROUND

Digital phase locked loops (DPLLs) are commonly used to synchronize a first clock signal (e.g., operating at a desired frequency) to a second clock (e.g., operating at a reference frequency). DPLLs commonly include a phase detector to detect and/or to operate on a phase difference between the first and second clocks. To facilitate the detection of the phase difference between the first and second clock signals, the first clock signal may be divided down by a factor of M, where M is a ratio of the desired frequency and the reference frequency, and is commonly restricted to an integer value. Other functional blocks typically included in DPLLs are a time digitizer to convert the detected phase into a digital control value, and a loop filter to filter the digital control value to reduce the effects of higher frequency noise. An output signal of the loop filter is then used to control an oscillator (e.g., a digitally controlled oscillator (DCO)) that generates the first (i.e., desired) clock signal.

### BRIEF DESCRIPTION OF THE DRAWINGS

FIG. 1 is a schematic diagram of example digital phase locked loop (DPLL) constructed in accordance with the teachings of the invention.

FIG. 2 is a schematic diagram of an example manner of implementing the example time converter of FIG. 1.

FIGS. 3A and 3B illustrate example operations of the example time converter of FIG. 2.

FIG. 4 is a schematic diagram of another example manner of implementing the example time converter of FIG. 1.

FIG. 5 is a schematic diagram of an example manner of implementing any or all of the example time digitizers described herein.

FIG. 6 is a schematic diagram of an example manner of implementing the example up/down sensor of FIG. 1.

FIG. 7 illustrates an example operation of the example up/down sensor of FIG. 6.

FIG. 8 is a schematic diagram of another example digital phase locked loop (DPLL) constructed in accordance with the teachings of the invention.

FIG. 9 is a schematic diagram of an example manner of implementing the example up/down sensor of FIG. 8.

FIG. 10 is a schematic diagram of an example manner of implementing any or all of the example phase detectors described herein.

FIG. 11 illustrates an example operation of the example up/down sensor of FIG. 9.

### DETAILED DESCRIPTION

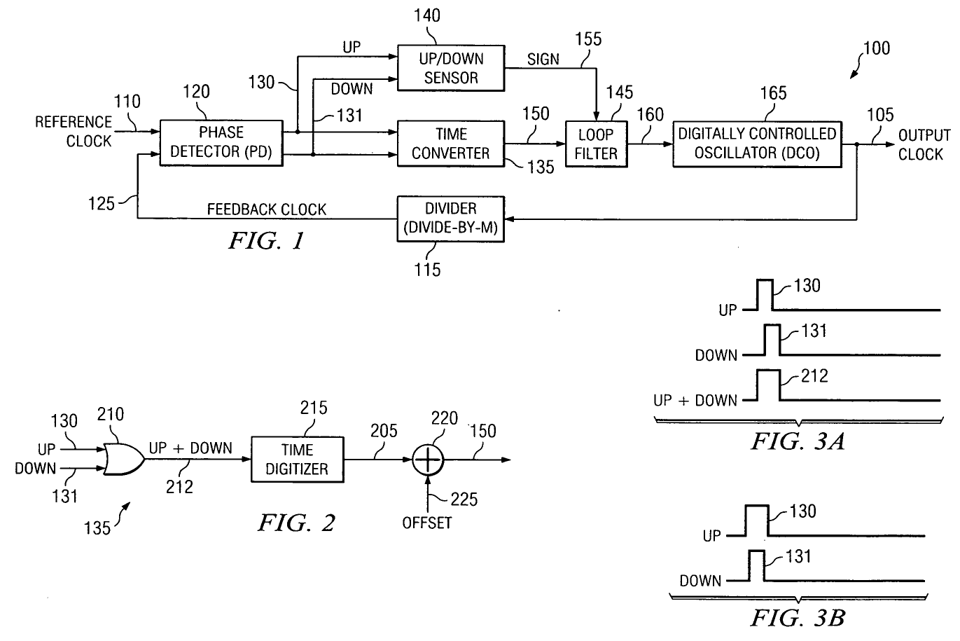

FIG. 1 is a schematic illustration of an example digital phase locked loop (DPLL) 100 that may be used to synchronize an output clock signal 105 to a reference clock signal 110. That is, to adjust the frequency of the output clock signal 105 such that the output clock signal 105 is frequency locked (has a fixed frequency relationship) to the reference clock signal 110. To detect the frequency lock of the output clock signal 105 to the reference clock signal 110, the example DPLL 100 of FIG. 1 includes any type of divider 115 and any type of phase detector 120. In the example DPLL 100 of FIG. 1, the ratio of the output clock signal 105 and the reference clock signal 110 is expressed by an integer M. Dividing the output clock signal 105 by M results in a feedback clock signal 125 having a frequency that, when the DPLL 100 has reached its steady state (i.e., in a locked state), is substantially similar to the frequency of the reference clock 110 (i.e., is substantially frequency locked). While the example DPLL 100 of FIG. 1 generates an output clock signal 105 having a higher frequency than the reference clock signal 110, persons of ordinary skill in the art will readily appreciate that other ratios of output clock signal 105 and reference clock signal 110 may be implemented.

Using any number and/or type(s) of circuit(s), logic and/or component(s), the example phase detector (PD) 120 of FIG. 1 detects, estimates and/or measures, at periodic and/or aperiodic sampling intervals, phase differences between the reference signal 110 and the feedback clock signal 125. For each phase difference, the example PD 120 generates and/or controls two digital-valued signals 130 and 131. For example, when a rising edge of the reference clock signal 110 occurs before a rising edge of the feedback clock signal 125, the PD 120 generates a logical high (e.g., 1.5 volts (V)) pulse on the signal 131 (e.g., an UP pulse) indicating that the frequency of the output signal 105 should be increased. Likewise, when the rising edge of the reference clock signal 110 occurs after the rising edge of the feedback clock signal 125, the PD 120 generates a logical high (e.g., 1.5 V) pulse on the signal 131 (e.g., a DOWN pulse) indicating that the frequency of the output signal 105 should be decreased. The length or duration of an UP or DOWN pulse 130, 131 depends upon the magnitude of the phase difference. A schematic diagram illustrating an example manner of implementing the example PD 120 of FIG. 1 is described below in connection with FIG. 10.

Ideally, only one of the signals 130 and 131 contains a pulse (e.g., is at a logical high value) at the same time. However, as the DPLL 100 approaches the locked condition (e.g., UP and DOWN pulses becoming shorter in duration) and due to, for example, implementation limitations (e.g., a maximum clock speed used to control the DPLL 100), both of the signals 130 and 131 may, in practice, be at a logical high at the same time. Such overlapping UP and DOWN pulses create and/or contribute to a condition commonly referred to in the industry as a DPLL dead-zone. A DPLL dead-zone may, in some implementations, limit and/or restrict the accuracy of the output clock signal 105 as measured by, for example, the jitter of the output clock signal 105.

To control the frequency of the output clock signal 105 based on the UP signal 130 and the DOWN signal 131, the example DPLL 100 of FIG. 1 includes a time converter 135, an up/down sensor 140 and a loop filter 145. The example time converter 135 of FIG. 1 converts the UP and DOWN signals 130 and 131 into a sequence of digital values 150 (i.e., a digital signal) that represents the duration of each pulse generated by the example PD 120. As described below in connection with FIGS. 2, 3A, 3B and 4, the example time converter 135 of FIG. 1 controls and/or adjusts the digital values 150 to reduce and/or substantially eliminate the dead-zone of the DPLL 100.

While the example time converter 135 digitizes the width of the UP and DOWN signals 130 and 131, the example loop filter 145 needs a sign value 155 for each of the digital values 150 (i.e., whether a particular digital value 150 represents an UP or a DOWN pulse). The example up/down sensor 140 of FIG. 1 generates a sequence of sign values 155 for respective ones of the digital values 150. Collectively, the digital values 150 and the sign values 155 represent a sequence of input signals to the example loop filter 145. An example manner of implementing the example up/down sensor 140 of FIG. 1 is described below in connection with FIG. 6.

The example loop filter 145 operates on the input signals defined by the digital values 150 and the sign values 155 to generate a control signal 160 that controls the frequency of the output clock signal 105 generated by any type of oscillator 165 (e.g., a digitally controlled oscillator (DCO)). An example loop filter 145 is a digital low-pass filter (LPF) having a corner frequency of approximately 10 percent (%) of the frequency of the reference clock signal 110.

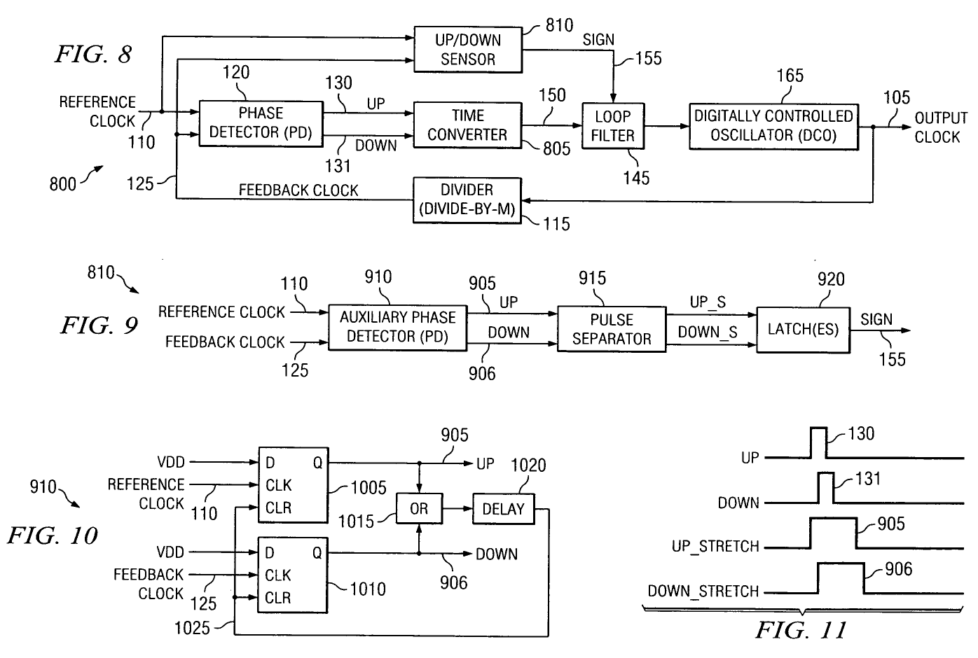

While an example DPLL 110 is illustrated in FIG. 1, the DPLL 100 may be implemented using any number and/or type(s) of alternative and/or additional logic, devices, components, circuits, modules, interfaces, etc. Further, the logic, devices, components, circuits, modules, elements, interfaces, etc. illustrated in FIG. 1 may be split, combined, re-arranged, eliminated and/or implemented in any way. For instance, FIG. 8 illustrates another example DPLL constructed in accordance with the teachings of the invention. Additionally, any or all of the example divider 115, the example PD 120, the example time converter 135, the example up/down sensor 140, the example loop filter 145, the example oscillator 165 and/or, more generally, the example DPLL 100 may be implemented as any combination of firmware, software, logic and/or hardware. Moreover, the example DPLL 100 may include one or more devices, logic, components, circuits, interfaces and/or modules instead of, or in additional to, those illustrated in FIG. 1 and/or may include more than one of any or all of the illustrated logic, devices, components, circuits, interfaces and/or modules.

FIG. 2 is a schematic illustration of an example manner of implementing the example time converter 135 of FIG. 1. The example time converter 135 of FIG. 2 converts the UP and DOWN signals 130 and 131 it receives from a phase detector (e.g., the example PD 120 of FIG. 1) into the sequence of digital values 150 (i.e., a digital signal) that represent the durations of pulses received via the signals 130 and 131. As described below, the example time converter 135 of FIG. 2 also controls and/or adjusts the digital values 150 to reduce and/or substantially eliminate the dead-zone of the DPLL that includes and/or implements the time converter 135.

To form a sequence of digital values 205 representing the durations of pulses received via the signals 130 and 131, the example time converter 135 of FIG. 2 includes a logical OR operator (e.g., an OR gate) 210 and any type of time digitizer 215. The example logical OR operator 210 forms a signal 212 representing the logical OR of the signals 130 and 131. FIG. 3A illustrates example inputs 130 and 131, and a corresponding example output 212 of the example logical OR operator 210. As illustrated in FIG. 3A, the UP and DOWN pulses 130 and 131 overlap creating a potentially erroneous combined signal 212 (i.e., UP+DOWN).

Returning to FIG. 2, the example time digitizer 215 of FIG. 2 creates a digital value 205 that represents the pulse width of each pulse present in the output signal 212 of the logical OR operator 210. An example manner of implementing the example time digitizer 215 is described below in connection with FIG. 5.

To reduce and/or substantially eliminate the dead-zone of the DPLL that includes and/or implements the example time converter 135 of FIG. 2, the time converter 135 includes an adder 220. The example adder 220 of FIG. 2 adds an offset 225 to each digital value 205 generated by the example time digitizer 215. In some examples, the value of the offset 225 is larger than the expected dead-zone of the DPLL. The addition of the offset 225 by the adder 220 biases the DPLL. In particular, the addition of the offset 225 causes a persistent offset between the rising edges of the reference clock signal 110 and the feedback clock signal 125 when the DPLL 100 is locked. Thus, the PDF generating the signals 130 and 131 regularly and/or continually produces an UP pulse 130 that is wider than the dead-zone and, thus, the DPLL 100 operates outside of the DPLL dead zone. For an opposite signed offset 225, the PDF generating the signals 130 and 131 would regularly and/or continually produce a DOWN pulse 131 that is wider than the dead-zone. FIG. 3B illustrates example inputs 130 and 131 that may occur when an offset 225 has been added by the example adder 220, for the same reference clock signal 110 and feedback clock signal 125 conditions. As illustrated in FIG. 3B, the UP pulse 130 has had its pulse width extended by the addition of the offset 225 such that a corresponding digital value 150 would substantially correspond with the UP pulse 130 (i.e., have the impact of the DOWN pulse 131 reduced).

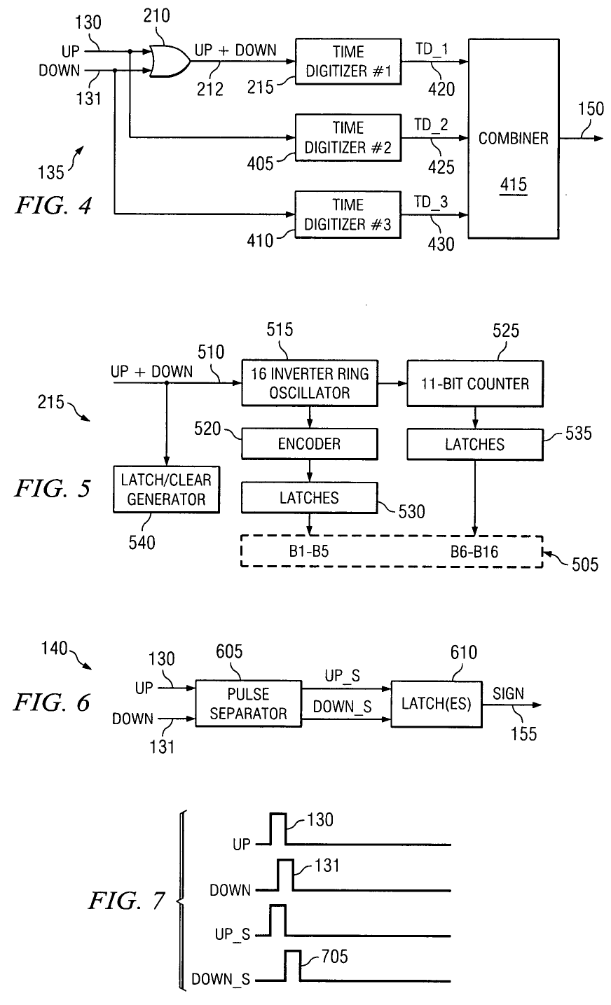

FIG. 4 is a schematic diagram illustrating another example manner of implementing the example time converter 135 of FIG. 1. To generate the digital values 150, the example time converter 135 of FIG. 4 includes two additional time digitizers 405 and 410, and a combiner 415. The example time digitizers 405 and 410 of FIG. 4 operate and/or are implemented substantially similar to the example time digitizer 215 described above in connection with FIG. 2. However, the time digitizers 405 and 410 have a short range (i.e., can not measure pulses that are as long as those measurable by the time digitizer 215). For example, the time digitizers 405 and 410 might only be capable of measuring pulse widths equal to the width of the DPLL dead-zone (e.g., two or three unit delays in length).

The example combiner 415 of FIG. 4 uses digital values 420, 425 and 430 generated, respectively, by the time digitizers 215, 405 and 410 to determine the digital values 150. For example, the combiner 415 may determine the digital values 150 the end of each pulse using the following logic:

If pulse_width(TD_1)≧Td, then use TD_1 as the digital value

If pulse_width(TD_1)<Td, then use (TD_2−TD_3) as the digital value, where Td is the pulse width of TD_2 and TD-3. In general, the example time digitizers 215, 405 and 410 and the combiner 415 of FIG. 4 mimic the behavior of an analog charge pump phase lock loop (PLL) in that, the UP and DOWN pulses 130 and 131 simultaneously pump a small amount of opposite charge into a capacitor when the UP and DOWN pulses 130 and 131 are very narrow (e.g., when the PLL is in a locked condition).

While example manners of implementing the example time converter 135 of FIG. 1 have been illustrated in FIGS. 3 and 4, the time converter 135 may be implemented using any number and/or type(s) of alternative and/or additional logic, devices, components, circuits, modules, interfaces, etc. Further, the logic, devices, components, circuits, modules, elements, interfaces, etc. illustrated in FIGS. 3 and/or 4 may be split, combined, re-arranged, eliminated and/or implemented in any way. Additionally, any or all of the example logical operator 210, the example time digitizers 215, 405 and 410, the example adder 220, the example combiner 415 and/or, more generally, the example time converter 135 may be implemented as any combination of firmware, software, logic and/or hardware. Moreover, the example time converter 135 may include one or more logic, devices, components, circuits, interfaces and/or modules instead of, or in addition to, those illustrated in FIGS. 3 and/or 4, and/or may include more than one of any or all of the illustrated logic, devices, components, circuits, interfaces and/or modules.

FIG. 5 is a schematic diagram illustrating an example manner of implementing any or all the example time digitizers 215, 405 and/or 410 of FIGS. 2 and/or 4. While any of the example time digitizers 215, 405 and 410 may be represented by the example device of FIG. 5, for ease of discussion the device of FIG. 5 will be referred to as time digitizer 215. To generate bits of a digital control word 505 that represents the pulse width of a pulse 510, the example time digitizer 215 of FIG. 5 includes any type of ring oscillator 515, any type of encoder 520, any type of counter 525, and any type and/or size of latches 530 and 535.

The example ring oscillator 515 of FIG. 5 is implemented using sixteen inverters and, for short pulses, the state of the inverters represents directly the width of the pulse 510. For longer pulses, the ring oscillator 515 performs more than one cycle of oscillation. The example counter 525 of FIG. 5 is an eleven-bit counter that counts oscillations of the ring oscillator 515. The example encoder 520 of FIG. 5 encodes the sixteen inverter state values into six bits B1-B5 that represent the length of the pulse width not accounted for by the example counter 515. At the end of each pulse, the example latches 530 and 535 capture the outputs of the encoder 520 and the counter 525 to form the digital word 505 for the pulse.

To control the operation of the example time digitizer 215 of FIG. 5, the time digitizer 215 includes any type of latch/clear generator 540. The example latch/clear generator 540 clears the state of the ring oscillator 515 and the counter 525 at the start of each pulse 510, and triggers the latches 525 and 530 at the end of each pulse 510.

While an example manner of implementing any or all of the example time digitizers 215, 405 and 410 have been illustrated in FIG. 5, the time digitizer 215 of FIG. 5 may be implemented using any number and/or type(s) of alternative and/or additional logic, devices, components, circuits, modules, interfaces, etc. Further, the logic, devices, components, circuits, modules, elements, interfaces, etc. illustrated in FIG. 5 may be split, combined, re-arranged, eliminated and/or implemented in any way. Additionally, any or all of the example inverter ring oscillator 515, the example encoder 520, the example counter 525, the example latches 525 and 530, the example latch/clear generator 540 and/or, more generally, the example time digitizer 215 of FIG. 5 may be implemented as any combination of firmware, software, logic and/or hardware. Moreover, the example time converter 135 may include one or more logic, devices, components, circuits, interfaces and/or modules instead of, or in addition to, those illustrated in FIG. 5, and/or may include more than one of any or all of the illustrated logic, devices, components, circuits, interfaces and/or modules.

FIG. 6 is a schematic diagram of an example manner of implementing the example up/down sensor 140 of FIG. 1. The example up/down sensor 140 of FIG. 6 determines sign values 155 associated with the UP and DOWN signals 130 and 131. In particular, the example up/down sensor 140 detects whether the UP pulse 130 or the DOWN pulse 131 came first. As discussed above, UP and DOWN pulses 130 and 131 may overlap in some circumstances (e.g., when the DPLL that implements and/or includes the up/down sensor 140 is in a locked state). To separate the pulses 130 and 131, the example up/down sensor 140 of FIG. 6 includes any type of pulse separator 605. Using any number and/or type(s) of logic, circuit(s) and/or component(s), the example pulse separator 605 of FIG. 6 adjusts the temporal location of one or more of the pulses 130 and 131 so that the pulses 130 and 131 no longer overlap. For example, as illustrated in FIG. 7, the pulse separator 605 delays the DOWN pulse 131 so that the delayed DOWN pulse 705 no longer overlaps with the UP pulse 130.

To generate the sign signal 155, the example up/down sensor 140 of FIG. 6 includes any type of latch(es) 610. At the end of each pulse, the example latch(es) 610 of FIG. 6 samples the separated pulses UP_S and DOWN_S to determine whether the frequency of the output clock signal 105 should be increased (e.g., a positive valued sign 155) or decreased (e.g., a negative valued sign 155). For example, the latch(es) 610 determines, at the end of each pulse, which one of the pulses UP_S and DOWN_S is at a logical high, and uses the same to control the sign. For instance, if the UP_S is at a logical high, the sign 155 would represent a positive sign (e.g., have a logical high value). Likewise, if the DOWN_S is at a logical high, the sign 155 would represent a negative sign (e.g., have a logical low value).

As the DPLL that implements and/or includes the example up/down sensor 140 of FIG. 1 approaches and/or is in a locked state, the pulses 130 and/or 131 have increasingly smaller pulse widths. In some example implementations, the support for very short pulses 130 and 131 increases one or more implementation complexities (e.g., clock speed, circuit size, power, etc.) of the pulse separator 605 and/or, more generally, the example up/down sensor 140. To wholly and/or partially reduce such increased implementation complexity, the DPLL 100 of FIG. 1 and/or the example up/down sensor 140 may alternatively be implemented and/or be configured as described below in connection with FIGS. 8 and 9.

While an example manner of implementing the example up/down sensor 140 of FIG. 1 has been illustrated in FIG. 6, the up/down sensor 140 may be implemented using any number and/or type(s) of alternative and/or additional logic, devices, components, circuits, modules, interfaces, etc. Further, the logic, devices, components, circuits, modules, elements, interfaces, etc. illustrated in FIG. 6 may be split, combined, re-arranged, eliminated and/or implemented in any way. Additionally, any or all of the example pulse separator 605, the example latch(es) 610 and/or, more generally, the example up/down sensor 140 may be implemented as any combination of firmware, software, logic and/or hardware. Moreover, the example up/down sensor 140 may include one or more logic, devices, components, circuits, interfaces and/or modules instead of, or in addition to, those illustrated in FIG. 6, and/or may include more than one of any or all of the illustrated logic, devices, components, circuits, interfaces and/or modules.

FIG. 8 is a schematic diagram of another example manner of implementing a DPLL 800 that may be used to synchronize the output clock signal 105 to the reference clock signal 110. Portions of the example DPLL 800 of FIG. 8 are identical to those discussed above in connection with FIG. 1 and, thus, the descriptions of those portions are not repeated here. Instead, identical elements are illustrated with identical reference numerals in FIGS. 1 and 8, and the interested reader is referred back to the descriptions presented above in connection with FIG. 1 for a complete description of those like-numbered elements.

The example time converter 805 of FIG. 8 may be substantially implemented as described above in connection with the example time converter 135 of FIGS. 1 and/or 2. Alternatively, the example time converter 805 may not include the example adder 220 of FIG. 2. In such examples, the time converter 805 would not introduce a bias into the DPPL 800 and, thus, not cause the PD 120 to always generate UP pulses 130 (or DOWN pulses 131) that are wider than the dead-zone of the DPLL 800. That is the example DPLL 800 of FIG. 8 may be implementing using a traditional time converter (e.g., the time converter 135 without the adder 220) and/or the enhanced example time converter 135 described above in connection with FIGS. 1 and 2.

To create sign values 155 for respective ones of the example digital values 150, the example DPLL 800 of FIG. 8 includes an up/down sensor 810. As described below in connection with FIG. 9, the example up/down sensor 810 is implemented to reduce one or more implementation complexities of the up/down sensor 810 required to support conditions that cause the PD 120 to generate very short UP and DOWN pulses 130 and 131. Unlike, the example up/down sensor 140 of FIG. 1, the example up/down sensor 810 of FIG. 8 uses the reference clock signal 110 and the feedback clock signal 125 as inputs.

While an example DPLL 800 is illustrated in FIG. 8, the DPLL 800 may be implemented using any number and/or type(s) of alternative and/or additional logic, devices, components, circuits, modules, interfaces, etc. Further, the logic, devices, components, circuits, modules, elements, interfaces, etc. illustrated in FIG. 8 may be split, combined, re-arranged, eliminated and/or implemented in any way. Additionally, any or all of the example divider 115, the example PD 120, the example time converter 805, the example up/down sensor 810, the example loop filter 145, the example DCO 165 and/or, more generally, the example DPLL 800 may be implemented as any combination of firmware, software, logic and/or hardware. Moreover, the example DPLL 800 may one or more logic, devices, components, circuits, interfaces and/or modules instead of, or in additional to, those illustrated in FIG. 8 and/or may include more than one of any or all of the illustrated logic, devices, components, circuits, interfaces and/or modules.

FIG. 9 is a schematic diagram of an example manner of implementing the example up/down sensor 810 of FIG. 8. To generate UP and DOWN pulses 905 and 906 that are longer than the example UP and DOWN pulses 130 and 131 of FIG. 1, even for the same reference clock signal 110 and feedback clock signal 125, the example up/down sensor 810 of FIG. 9 includes an auxiliary PD 910. The example auxiliary PD 910 of FIG. 9 may be implemented substantially similarly to the example PD 120 described above. An example manner of implementing the example PD 120 and/or the example PD 910 is described below in connection with FIG. 10. However, as discussed below, the example auxiliary PD 910 implements a longer delay in a feedback path used to control the pulse width of the UP and DOWN pulses 905 and 906 generated by the auxiliary PD 910, thereby reducing the implementation complexity of a pulse separator 915.

To separate the pulses 905 and 906, the example up/down sensor 810 of FIG. 9 includes a pulse separator 915. Using any number and/or type(s) of logic, circuit(s) and/or component(s), the example pulse separator 915 of FIG. 9 adjusts the temporal location of one or more of the pulses 905 and 906 so that the pulses 905 and 906 no longer overlap. For example, similar to the illustrated example of FIG. 7, the pulse separator 915 delays the DOWN pulse 906 so that the delayed DOWN pulse 705 no longer overlaps with the UP pulse 905. The example pulse separator 915 of FIG. 9 may be implemented substantially similar to the example pulse separator 605 of FIG. 6.

To generate the sign signal 155, the example up/down sensor 810 of FIG. 9 includes any type of latch(es) 920. At the end of each pulse, the example latch(es) 920 of FIG. 10 samples the separated pulses UP_S and DOWN_S to determine whether the frequency of the output clock signal 105 should be increased (e.g., a positive valued sign 155) or decreased (e.g., a negative valued sign 155). For example, the latch(es) 920 determines which one of the pulses UP_S and DOWN_S occurred first, and uses the same to control the sign 155. For instance, if the UP_S occurred first, the sign 155 would represent a positive sign (e.g., have a logical high value). Likewise, if the DOWN_S occurred first, the sign 155 would represent a negative sign (e.g., have a logical low value).

While an example manner of implementing the example up/down sensor 810 of FIG. 8 has been illustrated in FIG. 9, the up/down sensor 810 may be implemented using any number and/or type(s) of alternative and/or additional logic, devices, components, circuits, modules, interfaces, etc. Further, the logic, devices, components, circuits, modules, elements, interfaces, etc. illustrated in FIG. 9 may be split, combined, re-arranged, eliminated and/or implemented in any way. Additionally, any or all of the example auxiliary PD 910, the example pulse separator 915, the example latch(es) 920 and/or, more generally, the example up/down sensor 810 may be implemented as any combination of firmware, software, logic and/or hardware. Moreover, the example up/down sensor 810 may include one or more logic, devices, components, circuits, interfaces and/or modules instead of, or in addition to, those illustrated in FIG. 9, and/or may include more than one of any or all of the illustrated logic, devices, components, circuits, interfaces and/or modules.

FIG. 10 is a schematic diagram of an example manner of implementing any or all of the example PDs 120 and 910 described herein. While any of the example PDs 120 and 910 may be represented by the example of FIG. 10, the example device of FIG. 10 will be referred to as PD 910. To generate an UP pulse 905, the example PD 910 of FIG. 10 includes a first D type flip-flop 1005. When a rising edge of the reference clock signal 110 occurs, the output 905 of the flip-flop 1005 goes to a logical high (e.g., 1.5 V). Likewise, to generate a DOWN pulse 906 based on the feedback clock signal 125, the example PD 910 includes a second D type flip-flop 1010. Thus, if the phase of feedback clock signal 125 lags relative to the reference clock signal 110 (i.e., the rising edge of the reference clock signal 110 precedes the rising edge of the feedback clock signal 125), the first flip-flop 1005 will transition its output 905 to a logical high, thereby generating an UP pulse.

To clear the UP and DOWN pulses 905 and 906 a time period after the start of an UP or DOWN pulse, the example PD 910 of FIG. 10 includes an OR gate 1015 and a delay 1020. The output of the OR gate 1015 goes to a logical high (e.g., 1.5 V) when either of the UP and DOWN pulses 905 and 906 go to a logical high. The output of the OR gate 1015 is delayed by the delay 1020 to form a clear signal 1025 for both of the flip-flops 1005 and 1010. The amount of delay introduced by the delay 1020 adjusts the length of the pulses 905 and 906 generated by the PD 910. For example, a longer delay increases the length of the pulses 905 and 906. In particular, because the example PD 910 of FIG. 9 is to generate longer pulses to facilitate a less complex implementation of the example pulse separator 915, the example PD 910 of FIG. 9 implements a larger amount of delay in the delay 1020 than the example PD 120 of FIGS. 1 and/or 9. For example, FIG. 11 illustrates UP and DOWN pulses 130 and 131 generated by the example PD 120 of FIG. 9 compared to the UP and DOWN pulses 905 and 906 generated by the example PD 910 of FIG. 9.

While an example manner of implementing any or all the example PDs 120 and 910 has been illustrated in FIG. 10, the PDs 120 and 910 may be implemented using any number and/or type(s) of alternative and/or additional logic, devices, components, circuits, modules, interfaces, etc. Further, the logic, devices, components, circuits, modules, elements, interfaces, etc. illustrated in FIG. 10 may be split, combined, re-arranged, eliminated and/or implemented in any way. Additionally, any or all of the example PD 910 of FIG. 10 may be implemented as any combination of firmware, software, logic and/or hardware. Moreover, the example PD 910 may include one or more logic, devices, components, circuits, interfaces and/or modules instead of, or in addition to, those illustrated in FIG. 10, and/or may include more than one of any or all of the illustrated logic, devices, components, circuits, interfaces and/or modules.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A digital phase locked loop circuit comprising:
a phase detector to detect a phase difference between a reference signal and a feedback signal;
a time digitizer to convert the phase difference to a digital value; and
an adder to add an offset to the digital value, the offset selected to reduce a digital phase locked loop dead zone.

2. A digital phase locked loop circuit as defined in claim 1, at least one of the reference signal or the feedback signal is a clock signal.

3. A digital phase locked loop circuit as defined in claim 1, wherein the phase difference is represented by a digital pulse signal.

4. A digital phase locked loop circuit as defined in claim 3, wherein the phase difference is represented by a combination of the digital pulse signal and a second digital pulse signal.

5. A digital phase locked loop circuit as defined in claim 3, wherein the digital value represents a length of the digital pulse signal.

6. A digital phase locked loop circuit as defined in claim 1, wherein the offset increases a width of a first digital pulse signal relative to a second digital pulse signal, and wherein the phase detector is to generate the first and second digital pulse signals based on the phase difference.

7. A digital phase locked loop circuit as defined in claim 1, wherein the phase detector generates a first digital pulse representative of the phase difference, and further comprising:
a second phase detector to generate a second digital pulse based on the phase difference, the second digital pulse having a longer pulse width than the first digital pulse; and
a loop filter to operate on the digital value based on the second digital pulse, wherein the second digital pulse represents a sign of the digital value, and wherein an output of the loop filter is to control a frequency of an oscillator.

8. A digital phase locked loop circuit as defined in claim 7, wherein the first and second phase detectors are substantially identical, the first phase detector to use a first delay value in a feedback path, and the second phase detector to use a second delay value in a corresponding feedback path, wherein the first delay value is smaller than the second delay value.

9. A digital phase locked loop circuit as defined in claim 1, further comprising:
an up/down sensor to generate a sign signal;
a loop filter to operate on an output signal of the adder based on the sign signal;
an oscillator to generate an output signal based on an output signal of the loop filter; and
a divider to form the feedback signal based on the output signal.

10. A digital phase locked loop circuit comprising:
a first phase detector to detect a phase difference between a reference signal and a feedback signal, and to generate a first digital pulse signal based on the phase difference;
a time digitizer to form a digital value representative of a length of the first digital pulse signal;
a second phase detector to generate a second digital pulse signal based on the phase difference, the second digital pulse signal having a longer pulse width than the first digital pulse signal;
a loop filter to operate on the digital value based on the second digital pulse signal, wherein the second digital pulse signal represents a sign of the digital value, an output signal of the loop filter to control a frequency of an oscillator.

11. A digital phase locked loop circuit as defined in claim 10, wherein a pulse width of the second digital pulse signal is lengthened by the second phase detector relative to a length of the first digital pulse signal.

12. A digital phase locked loop circuit as defined in claim 10, wherein the first and second phase detectors are substantially identical, the first phase detector is to use a first delay value in a feedback path, and the second phase detector is to use a second delay value in a corresponding feedback path.

13. A digital phase locked loop circuit as defined in claim 12, wherein the first delay value is smaller than the second delay value.

14. A digital phase locked loop circuit as defined in claim 10, wherein the second phase detector is to generate a third digital pulse signal based on the phase difference, the second and third digital pulse signals are to be generated to collectively represent the phase difference, and further comprising a pulse separator to reduce an overlap between the second and third digital pulse signals.

15. A digital phase locked loop circuit as defined in claim 10, further comprising a latch to generate a sign signal based on the separated second and third digital pulse signals.

16. A digital phase locked loop circuit as defined in claim 10, further comprising a divider to generate the reference clock signal based on an output signal of the oscillator.

17. A digital phase locked loop circuit comprising:
a time converter to receive phase signals indicative of a phase difference between a reference signal and a feedback signal, wherein the time converter is to adjust a digital value to reduce a dead-zone of the digital phase locked loop circuit.

18. A digital phase locked loop circuit as defined in claim 17, wherein the digital value is adjusted by an offset.

19. A digital phase locked loop circuit as defined in claim 17, further comprising a time digitizer to form the digital value based on the phase difference between the reference signal and the feedback signal.

20. A digital phase locked loop circuit as defined in claim 17, further comprising an up/down sensor to detect a sign of the phase difference between the reference signal and the feedback signal.
